(19) United States
(12) Patent Application Publication
(10) Pub. No.: US 2018/0088628 A1
(43) Pub. Date: Mar. 29, 2018

(54) LEADFRAME FOR SURFACE MOUNTED CONTACT FINGERS

(71) Applicant: Intel Corporation, Santa Clara, CA (US)

(72) Inventor: Min-Tih Lai, Orangevale, CA (US)

(73) Assignee: Intel Corporation, Santa Clara, CA (US)

(21) Appl. No.: 15/278,236

(22) Filed: Sep. 28, 2016

(51) Int. Cl. G06F 1/16; H05K 1/18; H05K 1/11; H05K 3/40; H05K 3/30

(52) U.S. Cl. CPC G06F 1/1613; H05K 1/181; H05K 3/301; H05K 3/4007; H05K 1/111

(57) ABSTRACT

Aspects of the disclosure are directed to a printed circuit board and methods of making a printed circuit board. A printed circuit board strip can include a plurality of finger pads to receive metal contact fingers. The printed circuit board strip can also include a plurality of surface mount technology (SMT) solder pads on each of the printed circuit boards. One or more integrated circuit packages can be placed using SMT or pick-and-place techniques or similar techniques onto at least some of the SMT solder pads. The printed circuit board strip can also include a leadframe comprising metal contact fingers on the plurality of finger pads. The one or more integrated circuit packages and the leadframe comprising the metal contact fingers can be mechanically and electrically connected to printed circuit board strip through a solder process, such as that used in SMT or pick-and-place package assembly.

### TECHNICAL FIELD

This disclosure pertains to leadframe for contact fingers, and more particularly, to the formation and application of surface mounted contact fingers using a leadframe.

### BACKGROUND

Electronic devices need to provide more functionality at an ever shrinking form factor. Tablet and ultra-small (or ultra-thin) PCs require devices such as storage (SSD/HDD) and wireless modems (WiFi adaptor).

FIG. 1 is a schematic diagram of an example edge-card 100. The edge card has a “gum-stick” form factor. The “gum-stick” form factor edge-card connection allows for hardware swapping and upgrades, and has a thickness and X-Y footprint that takes up valuable real estate in the device. The example in FIG. 1 shows a basic “gum-stick” SSD card design 100 with components on one side. Components include an ASIC 102a, flash memory 102b-c, and passive components 104. Each of the three types of components (and the edge card connector itself) contribute to the X dimension of the card, and the total thickness (Z dimension) is defined by the thickest component plus the thickness of the card. Typically, the total Z dimension of the card (˜1 mm) with the flash packaging and other components (˜1 mm) is on the order of 2 mm.

### BRIEF DESCRIPTION OF THE DRAWINGS

FIG. 1 is a schematic diagram of an edge card having a gum-stick form factor.

FIG. 2 is a schematic diagram of an edge card having surface mounted contact fingers in accordance with embodiments of the present disclosure.

FIG. 3 is a schematic diagram of a leadframe stamped from a copper foil in accordance with embodiments of the present disclosure.

FIGS. 4A-D are schematic diagrams illustrating an example assembly procedure for forming edge cards in accordance with embodiments of the present disclosure.

FIG. 5 is a schematic diagram of placement of a leadframe onto an edge card strip in accordance with embodiments of the present disclosure.

FIG. 6 is a block diagram of an example computing device that may connected via a linear edge connector.

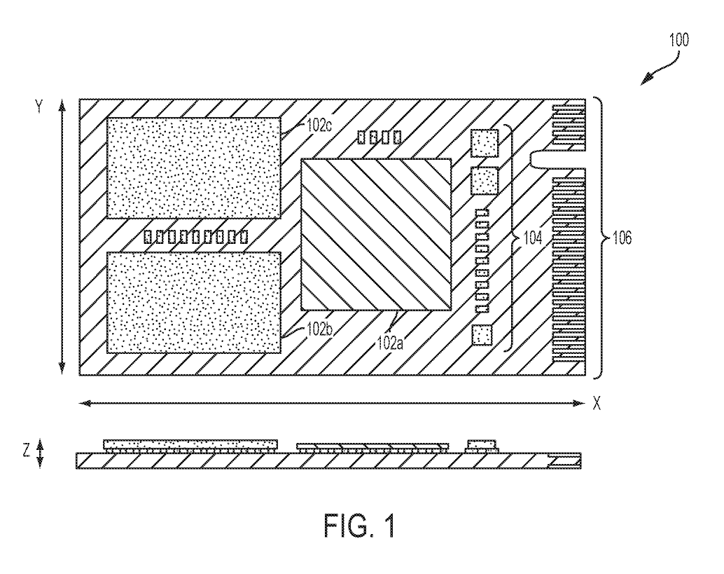

### DETAILED DESCRIPTION

This disclosure describes an edge card that can accommodate passive and active electronic components for providing computing and/or memory functionality. This disclosure describes using surface mount technology (SMT) to place fingers that make up the Z-height requirement of edge card connectors, allowing for the rest of the device to be placed on a thin PCB substrate, thus reducing the Z (and by extension X and Y) dimension of the edge card. The thin PCB substrate can be similar to those used in packaging.

This disclosure uses the strip-based nature of device manufacturing to allow for the placement of all the fingers at once in the form of a leadframe. During singulation, this leadframe would be cut, leaving only the desired fingers in each device.

The leadframe of fingers can be manufactured inexpensively by a die stamp process. Leadframes can be manufactured in a manner similar to that of thin small outline package (TSOP) components, leveraging manufacturing techniques to acquire (and improve) tolerances while also controlling costs. Leadframes can be placed in a single assembly step, as will be described below, as opposed to in more than one step for each finger or set of fingers. The use of leadframes can reduce number of inventory items that are required and also reduces through-put time for manufacturing and assembly.

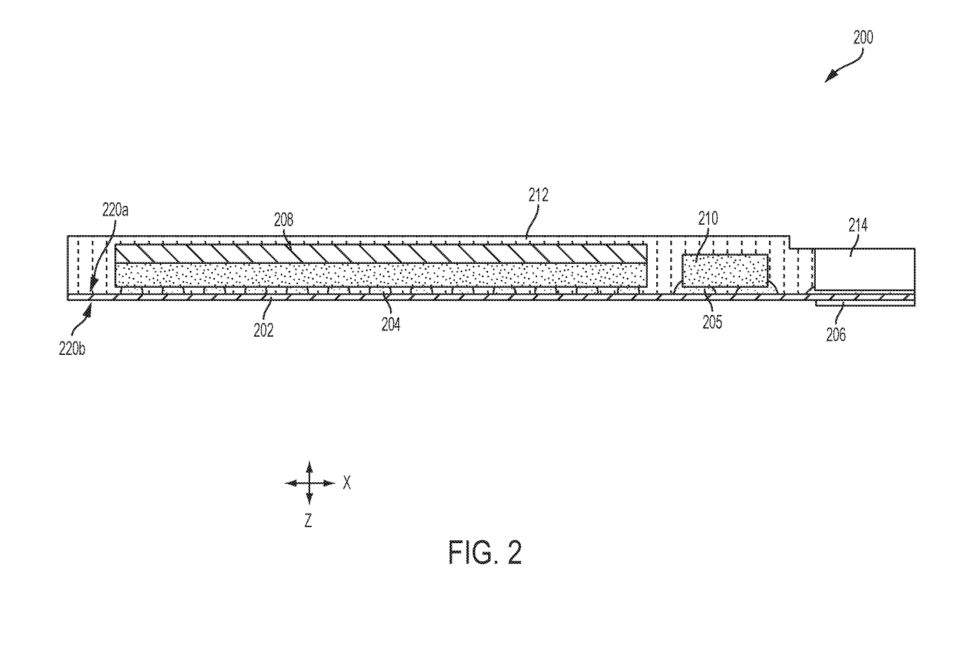

FIG. 2 is a schematic diagram of an edge card 200 having surface mounted contact fingers in accordance with embodiments of the present disclosure. The edge card 200 of FIG. 2 illustrates an edge card that has been manufactured using the techniques described herein. The edge card 200 includes a printed circuit board (PCB) 202, which can be a thin substrate style of PCB. The PCB 202 can include a plurality of solder balls 204 on a “top” side 220a of the PCB 202 that can electrically and mechanically connect the edge card components 208 to the PCB 202. In embodiments, the edge card components 208 can be stacked to reduce the size of the edge card 200 in the X and/or Y directions. Components 208 can be a flash card, ASIC, or other component, or can be a combination of components, such as components stacked on top of each other.

The PCB 202 can include pre-patterned metal contact fingers 206 on a “bottom” side 220b of the PCB 202 proximate to an edge of the edge card 200. On the top side 220a of the PCB 202, in a similar location to the pre-patterned metal contact fingers 206, a surface mount technology (SMT) pad can be formed to receive a plurality of metal fingers, which together form metal contact fingers on the top side 220a of the edge card 200. The shape and size of the metal fingers conforms to the corresponding connector into which the edge card 200 would fit.

The PCB 202 also includes one or more passive components 210 that are electrically and mechanically connected to the PCB 202 via solder balls 205.

The edge card 200 in FIG. 2 includes a thin PCB technology that allows the total Z dimension of the card, inclusive of the components, to be reduced (e.g., by on the order of 50%). Additionally, the edge card 200 and corresponding methods of manufacturing and assembly make it possible to make System in Package assemblies into edge card connectors through a bill of materials change. The edge card 200 can include an overmold 212 to add protection and rigidity to the edge card components. The overmold 212 can be processed, as described below, so that the metal fingers 214 that make up the contact fingers as well as the patterned metal contact finger 206 will fit into a corresponding receiver, such as a receiver with spring-mounted contacts that engage each metal finger on the edge card 200.

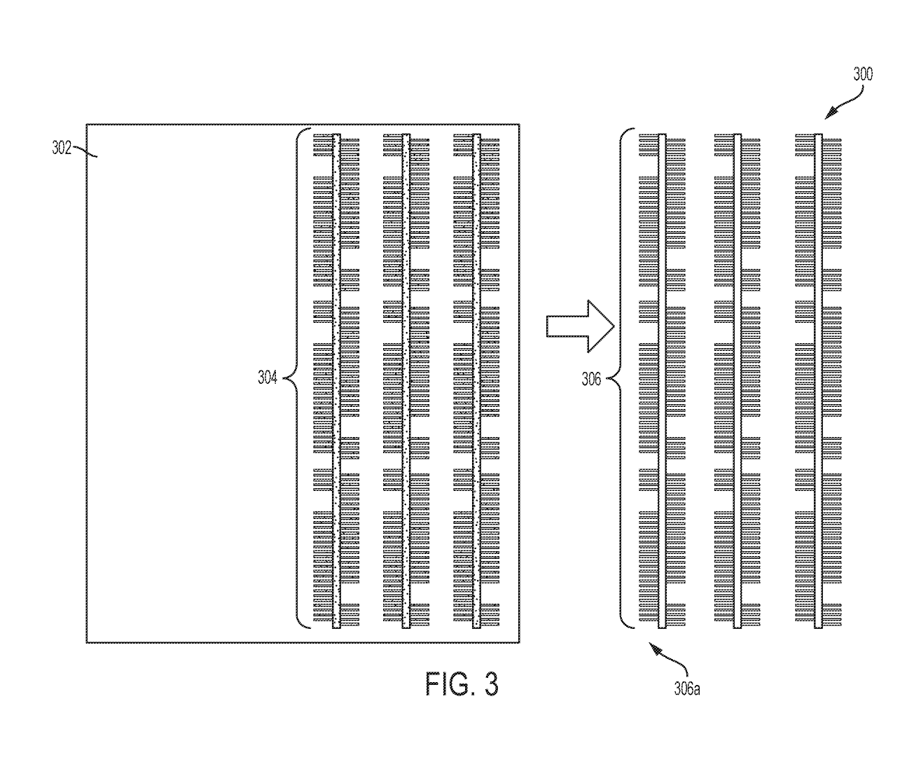

FIG. 3 is a schematic diagram of a leadframe 306 stamped from a copper foil 302 in accordance with embodiments of the present disclosure. The leadframe 306 can be patterned to conform to a shape and size of a desired edge card, such as edge card 200 of FIG. 2. The leadframe 306 can also be patterned to have a desired pitch (e.g., number of fingers and gap between each finger). FIG. 3 shows the copper foil 302 having a negative space 304 representative of the set of leadframes 306.

Example leadframe 306a includes 6 sets of metal contact fingers, 3 on each side, though the number of fingers, set of fingers, and other metrics can be different depending on the application. As can be seen, the stamping process can result in a high number of parts that are easy to make, ship, and assemble onto the edge card.

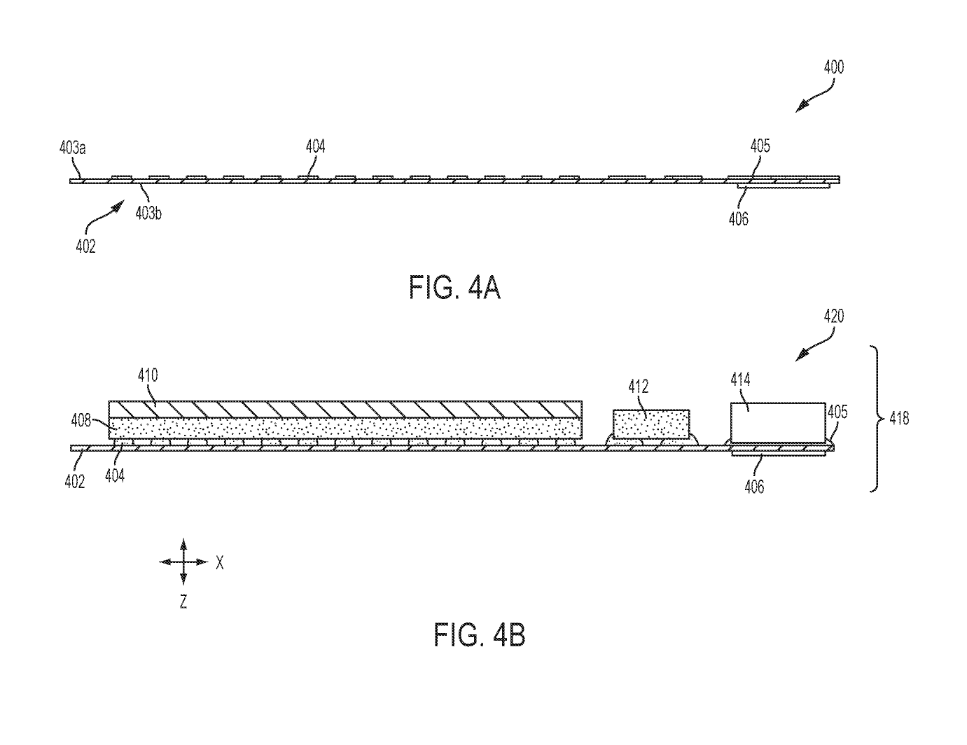

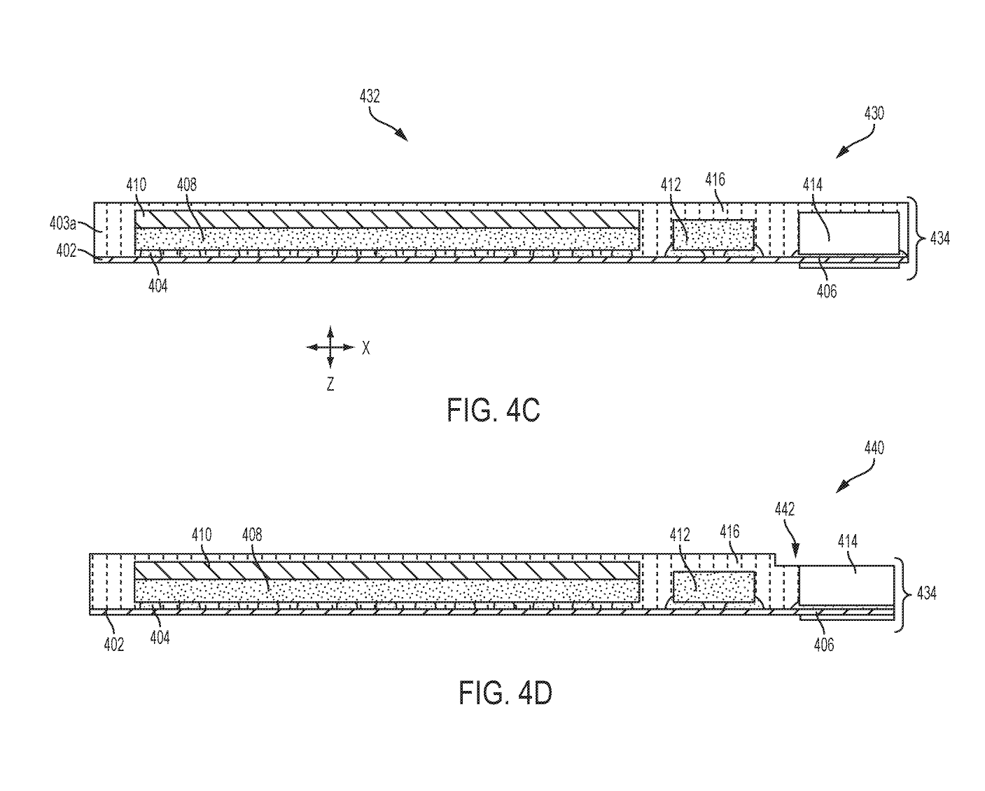

FIGS. 4A-D are schematic diagrams illustrating an example assembly procedure for forming edge cards in accordance with embodiments of the present disclosure. FIG. 4A illustrates a preliminary preparation stage 400 for PCB 402. In FIG. 4A, a thin PCB package substrate 402 can be pre-patterned on a bottom side 403b with gold fingers 406, while SMT pads 404 are formed on the top side 403a of the PCB 402.

FIG. 4B illustrates an assembly step 420. In FIG. 4B, the surface mount technology (SMT) components, such as flash memory 408 and/or ASIC 410, as well as passive components 412, are placed first onto SMT pads 404. The flash memory 408 and the ASIC 410 are shown to be stacked in FIG. 4B. Direct IC die bonding is also possible, including flip-chip, and die stacked wirebonds.

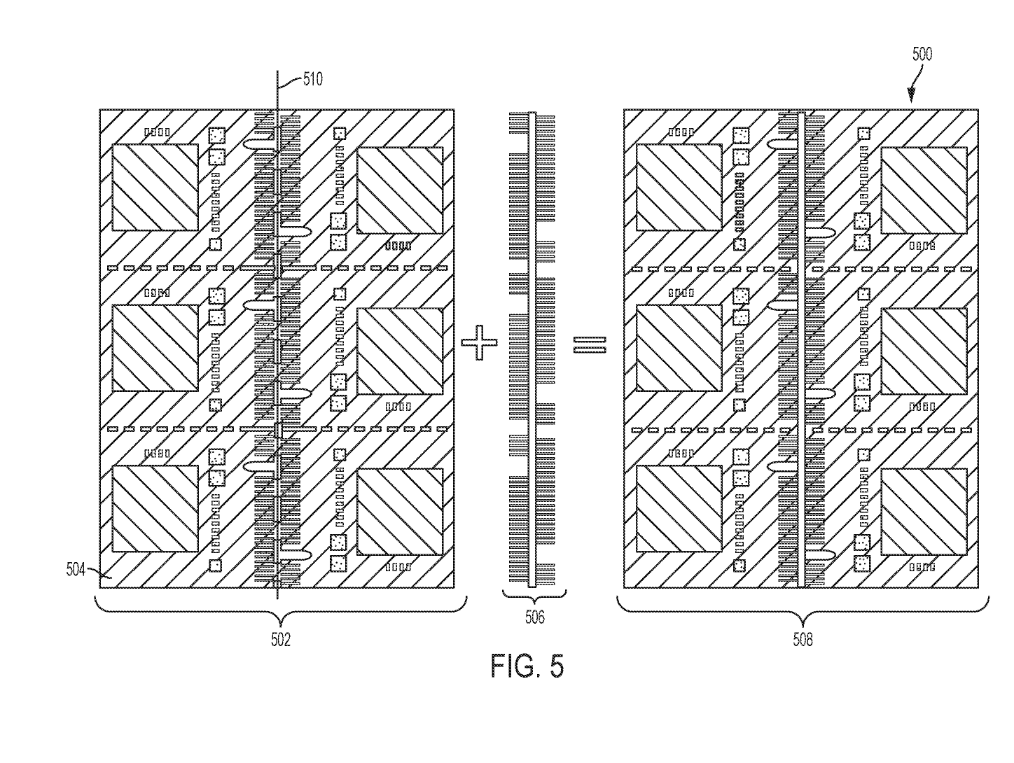

The metal contact fingers 414 can be placed onto the SMT pad 405 in a similar was as the SMT components described above. Turning briefly to FIG. 5, FIG. 5 is a schematic diagram 500 of leadframe placement onto a printed circuit board strip 502 in accordance with embodiments of the present disclosure. FIG. 5 is a top down view of a printed circuit board strip 502. As an example, printed circuit board 504 is analogous to edge card 200 and the edge card being formed in FIG. 4B. The printed circuit board 502 shown in FIG. 5 include edge cards having all of the features described in FIGS. 4A-B, with the exception of the metal contact fingers. FIG. 5 illustrates an embodiment for the placement of the leadframe 506 onto the printed circuit board strip 502, which forms the metal contact fingers onto the printed circuit board 504.

Leadframe 506 is analogous to leadframe 306a shown in FIG. 3. As an example, leadframe 506 includes 6 sets of metal contact fingers, with 3 on each side, though the number of sets of metal contact fingers on a leadframe is not limited to 6. The formation of the leadframe 506 allows placement of the leadframe onto the set of edge cards 502 prior to singulation. The edge card 418 shown in FIG. 4B is a side-view of the edge card 504 shown in a top-view in FIG. 5 and as part of an edge card strip 502.

Returning to FIG. 4B, solder can be introduced, such as a solder paste, and the solder is reflowed through heating the PCB 302. The solder reflows to connect the SMT components 308, 310, and/or 312 and the metal contact fingers 314 to the PCB 302.

Returning to FIG. 4C, FIG. 4C illustrates an overmolding step 430. In embodiments, a mold chase presses down on the edge card strip (e.g., edge card strip 502 in FIG. 5) and liquid mold compound floods the top side of the edge card strip. When the liquid mold hardens, the resulting hardened mold 416 provides rigidity to the card (e.g., shown as 432 in FIG. 4C) and the edge connector 434.

FIG. 4D illustrates a singulation and grind back step 440. In embodiments, singulation of the edge card from the edge card strip creates an edge card having the metal contact fingers 414 and 406 at the edge of the edge card. The grind-back step exposes the fingers to the surface and conforms the edge of the card to the connector specifications. The grind back processes can remove excess overmolding from the edge of the edge card, and can also create a substantially flush surface for the edge connector. This grind-back is shown as a negative space 442, as well as by illustrating a flush edge for edge connector 434 from the pre-patterned metal contact 406 to the metal contact fingers 414. The fingers are exposed and are free to make electrical and mechanical contact with a connector.

Another possibility (not drawn) is to use a mold chase specially designed to make contact with the solder fingers, this requires more specialized tooling but negates the need for a grind back step.

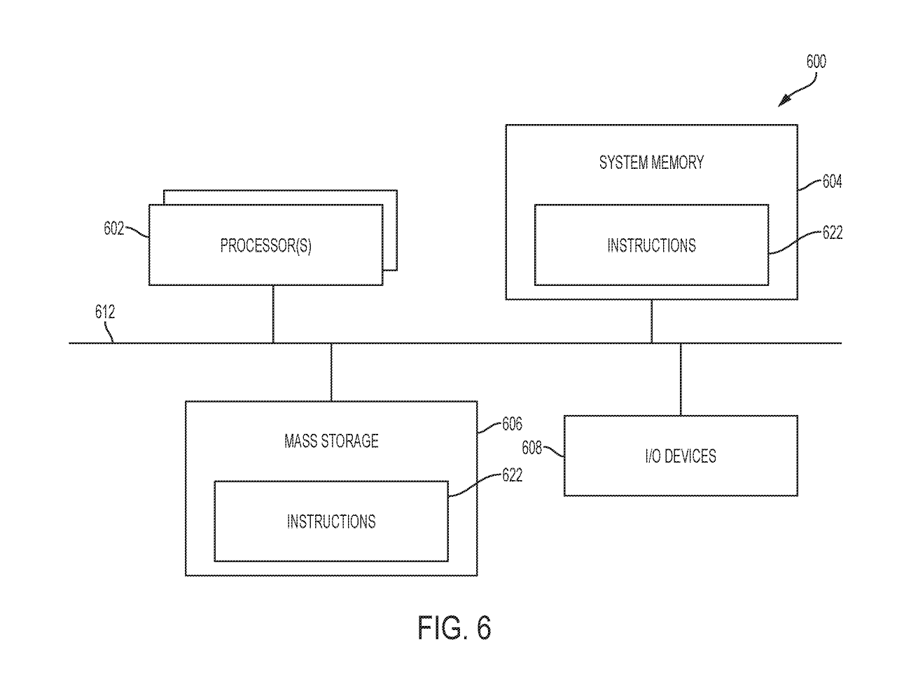

FIG. 6 is a block diagram of an example computing device 600 that may be connected via a linear edge connector. As shown, the computing device 600 may include one or more processors 602 (e.g., one or more processor cores implemented on one or more components) and a system memory 604 (implemented on one or more components). As used herein, the term “processor” or “processing device” may refer to any device or portion of a device that processes electronic data from registers and/or memory to transform that electronic data into other electronic data that may be stored in registers and/or memory. The processor(s) 602 may include one or more microprocessors, graphics processors, digital signal processors, crypto processors, or other suitable devices. More generally, the computing device 600 may include any suitable computational circuitry, such as one or more Application Specific Integrated Circuits (ASICs).

The computing device 600 may include one or more mass storage devices 606 (such as flash memory devices or any other mass storage device suitable for inclusion in a flexible IC package). The system memory 604 and the mass storage device 606 may include any suitable storage devices, such as volatile memory (e.g., dynamic random access memory (DRAM)), nonvolatile memory (e.g., read-only memory (ROM)), and flash memory. The computing device 600 may include one or more I/O devices 608 (such as display, user input device, network interface cards, modems, and so forth, suitable for inclusion in a flexible IC device). The elements may be coupled to each other via a system bus 612, which represents one or more buses.

Each of these elements may perform its conventional functions known in the art. In particular, the system memory 604 and the mass storage device 606 may be employed to store a working copy and a permanent copy of programming instructions 622.

The permanent copy of the programming instructions 622 may be placed into permanent mass storage devices 606 in the factory or through a communication device included in the I/O devices 608 (e.g., from a distribution server (not shown)). The constitution of elements 602-612 are known, and accordingly will not be further described.

The linear edge connectors disclosed herein can be used to couple any suitable computing devices, such as coupling the processor 602 to another device (e.g., a network device), processor,

Machine-accessible media (including non-transitory computer-readable storage media), methods, systems, and devices for performing the above-described techniques are illustrative examples of embodiments disclosed herein for a linear edge connector. For example, a computer-readable media (e.g., the system memory 604 and/or the mass storage device 606) may have stored thereon instructions (e.g., the instructions 622) such that, when the instructions are executed by one or more of the processors 602.

In various embodiments, the computing device 600 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The relative sizes of features shown in the figures are not drawn to scale.

The following paragraphs provide examples of various ones of the embodiments disclosed herein.

Example 1 is a method of manufacturing an edge card, the method including providing a printed circuit board strip; forming a plurality of SMT pads on the printed circuit board strip, the SMT pads comprising a plurality of surface mount technology (SMT) finger pads to receive metal contact fingers; providing one or more integrated circuit packages onto the printed circuit board strip on at least some of the SMT pads; providing a leadframe comprising metal contact fingers onto at least some of the plurality of finger pads; providing a solder paste onto the printed circuit board strip; and heating the printed circuit board strip to reflow the solder paste on the printed circuit board strip.

Example 2 may include the subject matter of example 1, wherein the leadframe is stamped from metal foil.

Example 3 may include the subject matter of any of examples 1-2, and also can also include providing one or more passive circuit components onto at least some of the SMT pads.

Example 4 may include the subject matter of any of examples 1-3, and can also include forming an overmold on the printed circuit board strip.

Example 5 may include the subject matter of example 4, wherein forming the overmold can include providing a liquid mold onto the printed circuit board strip; and curing the liquid mold to form an overmold on the printed circuit board strip, the overmold covering the leadframe and the one or more integrated circuit packages.

Example 6 may include the subject matter of any of examples 1-5, and can also include forming an overmold on the printed circuit board strip, wherein forming the overmold comprises placing a mold chase on a top side of the printed circuit board strip that covers the one or more integrated circuit packages to form an overmold over the integrated circuit packages and leaving exposed the metal contact fingers.

Example 7 may include the subject matter of any of examples 1-6, and can also include splitting the printed circuit board strip to form a plurality of printed circuit boards.

Example 8 may include the subject matter of example 7, and can also include grinding the overmold to expose the metal contact fingers.

Example 9 may include the subject matter of example 8, and can also include grinding each of the plurality of printed circuit boards to create a flat edge on the printed circuit boards and the metal contact fingers.

Example 10 may include the subject matter of any of examples 1-9, wherein the printed circuit board strip comprises a printed circuit board thin substrate.

Example 11 may include the subject matter of any of examples 1-10, wherein providing one or more integrated circuit packages onto the printed circuit board strip on at least some of the SMT solder pads can also include stacking a first integrated circuit package on top of a second integrated circuit package.

Example 12 may include the subject matter of any of examples 1-11, and can also include providing a solder pad on one or both of an upperside or underside of the printed circuit board strip; and forming metal contact fingers on the solder pad on the upperside or underside of the printed circuit board strip.

Example 13 is a printed circuit board strip that includes a printed circuit board strip comprising a plurality of finger pads to receive metal contact fingers; a plurality of surface mount technology (SMT) solder pads on the printed circuit board strip; one or more integrated circuit packages residing on the SMT solder pads and mechanically and electrically connected to the printed circuit board via at least some of the SMT solder pads; and a leadframe comprising metal contact fingers mechanically and electrically connected to printed circuit board strip via the plurality of finger pads.

Example 14 may include the subject matter of example 13, wherein the leadframe is stamped from metal foil.

Example 15 may include the subject matter of any of examples 13-14, and can also include one or more passive circuit components mechanically and electrically connected to the printed circuit board strip via at least some of the SMT solder pads.

Example 16 may include the subject matter of any of examples 13-15, and can also include an overmold on the printed circuit board strip.

Example 17 may include the subject matter of example 16, wherein the overmold on the printed circuit board strip covers the one or more integrated circuits, and wherein the leadframe is exposed.

Example 18 may include the subject matter of any of examples 13-17, wherein the printed circuit board strip comprises a printed circuit board thin substrate.

Example 19 may include the subject matter of any of examples 13-18, wherein the one or more integrated circuit packages placed onto the printed circuit board on at least some of the SMT solder pads are in a stacked configuration.

Example 20 may include the subject matter of any of examples 13-19, and can also include a solder pad on one or both of an underside or an upperside of the printed circuit board strip; and a plurality of metal contact fingers on the solder pad on the underside or upperside of the printed circuit board strip.

Example 21 is a method of manufacturing an edge card, the method including providing a printed circuit board strip; forming a plurality of SMT pads on the printed circuit board, the SMT pads comprising a plurality of surface mount technology (SMT) finger pads to receive metal contact fingers; placing a leadframe comprising metal contact fingers onto at least some of the plurality of finger pads; providing a solder paste onto the printed circuit board; and heating the printed circuit board to reflow the solder paste on the printed circuit board.

Example 22 may include the subject matter of example 21, wherein placing the leadframe onto the metal contact fingers comprises picking and placing the leadframe onto the metal contact fingers.

Example 23 may include the subject matter of any of examples 21-22, and can also include placing one or more SMT components onto the SMT pads prior to providing the solder paste.

Example 24 may include the subject matter of any of examples 21-23, wherein the printed circuit board strip comprises a printed circuit board thin substrate.

Example 25 may include the subject matter of any of examples 21-24, wherein the leadframe is stamped from metal foil.

1. A method of manufacturing an edge card, the method comprising:
providing a printed circuit board strip;
forming a plurality of SMT pads on the printed circuit board strip, the SMT pads comprising a plurality of surface mount technology (SMT) finger pads to receive metal contact fingers;
providing one or more integrated circuit packages onto the printed circuit board strip on at least some of the SMT pads;
providing a leadframe comprising metal contact fingers onto at least some of the plurality of finger pads;
providing a solder paste onto the printed circuit board strip; and
heating the printed circuit board strip to reflow the solder paste on the printed circuit board strip.

2. The method of claim 1, wherein the leadframe is stamped from metal foil.

3. The method of claim 1, further comprising providing one or more passive circuit components onto at least some of the SMT pads.

4. The method of claim 1, further comprising forming an overmold on the printed circuit board strip.

5. The method of claim 4, wherein forming the overmold comprises:
providing a liquid mold onto the printed circuit board strip; and
curing the liquid mold to form an overmold on the printed circuit board strip, the overmold covering the leadframe and the one or more integrated circuit packages.

6. The method of claim 4, further comprising:
forming an overmold on the printed circuit board strip, wherein forming the overmold comprises placing a mold chase on a top side of the printed circuit board strip that covers the one or more integrated circuit packages to form an overmold over the integrated circuit packages and leaving exposed the metal contact fingers.

7. The method of claim 4, further comprising:
splitting the printed circuit board strip to form a plurality of printed circuit boards.

8. The method of claim 7, further comprising grinding the overmold to expose the metal contact fingers.

9. The method of claim 8, further comprising grinding each of the plurality of printed circuit boards to create a flat edge on the printed circuit boards and the metal contact fingers.

10. The method of claim 1, wherein the printed circuit board strip comprises a printed circuit board thin substrate.

11. The method of claim 1, wherein providing one or more integrated circuit packages onto the printed circuit board strip on at least some of the SMT solder pads comprises stacking a first integrated circuit package on top of a second integrated circuit package.

12. The method of claim 1, further comprising:
providing a solder pad on one or both of an upperside or underside of the printed circuit board strip; and
forming metal contact fingers on the solder pad on the upperside or underside of the printed circuit board strip.

13. A printed circuit board strip comprising:
a printed circuit board strip comprising a plurality of finger pads to receive metal contact fingers;
a plurality of surface mount technology (SMT) solder pads on the printed circuit board strip;
one or more integrated circuit packages residing on the SMT solder pads and mechanically and electrically connected to the printed circuit board via at least some of the SMT solder pads; and
a leadframe comprising metal contact fingers mechanically and electrically connected to printed circuit board strip via the plurality of finger pads.

14. The printed circuit board strip of claim 13, wherein the leadframe is stamped from metal foil.

15. The printed circuit board strip of claim 13, further comprising one or more passive circuit components mechanically and electrically connected to the printed circuit board strip via at least some of the SMT solder pads.

16. The printed circuit board strip of claim 13, further comprising an overmold on the printed circuit board strip.

17. The printed circuit board strip of claim 16, wherein the overmold on the printed circuit board strip covers the one or more integrated circuits, and wherein the leadframe is exposed.

18. The printed circuit board strip of claim 13, wherein the printed circuit board strip comprises a printed circuit board thin substrate.

19. The printed circuit board strip of claim 13, wherein the one or more integrated circuit packages placed onto the printed circuit board on at least some of the SMT solder pads are in a stacked configuration.

20. The printed circuit board strip of claim 13, further comprising:
a solder pad on one or both of an underside or an upperside of the printed circuit board strip; and
a plurality of metal contact fingers on the solder pad on the underside or upperside of the printed circuit board strip.

21. A computing device comprising:
a processor mounted on a substrate;
a communications logic unit within the processor;
a memory within the processor;
a graphics processing unit within the computing device;
an antenna within the computing device;
a display on the computing device;
a battery within the computing device;
a power amplifier within the processor; and
a voltage regulator within the processor;
wherein the computing device comprises:
a printed circuit board strip comprising:
a printed circuit board strip comprising a plurality of surface mount technology (SMT) finger pads to receive metal contact fingers; and
a leadframe comprising metal contact fingers mechanically and electrically connected to printed circuit board strip via the plurality of finger pads.

22. The computing device of claim 21, wherein the leadframe is stamped from metal foil.

23. The computing device of claim 21, further comprising one or more passive circuit components mechanically and electrically connected to the printed circuit board strip via at least some of the SMT solder pads.

24. The computing device of claim 21, wherein the printed circuit board strip comprises a printed circuit board thin substrate.

25. The computing device of claim 21, further comprising:
a plurality of SMT solder pads on the printed circuit board strip; and
one or more integrated circuit packages residing on the SMT solder pads and mechanically and electrically connected to the printed circuit board via at least some of the SMT solder pads.
